(19) United States
(12) Patent Application Publication
(10) Pub. No.: US 2010/0142578 A1
(43) Pub. Date: Jun. 10, 2010

(54) SURFACE-EMITTING LASER INCLUDING TWO-DIMENSIONAL PHOTONIC CRYSTAL

(75) Inventors: Katsuyuki Hoshino, Tokyo (JP); Yasuhiro Nagatomo, Hachioji-shi (JP)

Correspondence Address: CANON U.S.A. INC. INTELLECTUAL PROPERTY DIVISION, 15975 ALTON PARKWAY, IRVINE, CA, 92618-3731, US

(73) Assignee: CANON KABUSHIKI KAISHA, Tokyo (JP)

(21) Appl. No.: 12/632,391

(22) Filed: Dec. 7, 2009

(30) Foreign Application Priority Data
Dec. 8, 2008 (JP) 2008-311864
Apr. 24, 2009 (JP) 2009-105939

(51) Int. Cl. H01S 5/10

(52) U.S. Cl. 372/45.01

(57) ABSTRACT

A surface-emitting laser includes an active layer and a two-dimensional photonic crystal and has a resonance mode in an in-plane direction of the two-dimensional photonic crystal. The two-dimensional photonic crystal is composed of a semiconductor and dielectric material that has a refractive index different from that of the semiconductor and acts as the photonic crystal holes being arranged into a two-dimensional periodical structure. When the lattice constant of the two-dimensional photonic crystal is a and the radius of the dielectric material acting as the photonic crystal holes is r, r≧0.22a. The dielectric material has a refractive index that causes the coupling coefficient of the two-dimensional photonic crystal to exhibit an increasing tendency as the distance between the active layer and the two-dimensional photonic crystal shortens.

### BACKGROUND OF THE INVENTION

1. Field of the Invention

The present invention relates to a surface-emitting laser including a two-dimensional photonic crystal.

2. Description of the Related Art

Surface-emitting lasers that use two-dimensional photonic crystals as resonant reflectors have been known as one type of surface-emitting lasers. In particular, in the field of surface-emitting lasers fabricated in nitride semiconductors that can emit light in the near ultraviolet to green ranges, it is difficult to fabricate commonly used distributed Bragg reflectors, and therefore surface-emitting lasers with two-dimensional photonic crystals are extensively investigated.

Japanese Patent Laid-Open No. 2006-165309 discloses the following semiconductor laser device as a surface-emitting laser including a two-dimensional photonic crystal. In this semiconductor laser device, an n-type GaN layer, an active layer, and a p-type GaN layer are sequentially formed on an electrically conductive GaN substrate, and the p-type GaN layer is dry etched to form the two-dimensional photonic crystal.

Then the substrate with the two-dimensional photonic crystal is fusion-bonded by using a lamination technique onto a semiconductor layer composed of p-type GaN formed on another substrate to form a semiconductor laser.

According to the semiconductor laser having such a structure, the distance between the active layer and the photonic crystal can be freely set. Emitting light from the active layer can be highly efficiently introduced into the photonic crystal by shortening the distance between the active layer and the photonic crystal.

Japanese Patent Laid-Open No. 2008-130731 discloses a surface-emitting laser with a photonic crystal layer formed without using a fusion bonding technique, by forming a dielectric film in holes of the two-dimensional photonic crystal layer to avoid filling the holes with a subsequently formed semiconductor layer. According to this structure, the distance between the active layer and the two-dimensional photonic crystal can be freely set.

Moreover, the technology disclosed in the '731 document can avoid damaging devices by fusion bonding and a difficulty of performing fusing-bonding on undulated photonic crystal layer.

According to Japanese Patent Laid-Open Nos. 2006-165309 and 2008-130731 described above, the holes in the two-dimensional photonic crystal may be left unfilled (filled with air) or filled with a material having a low refractive index. As a result, the difference in refractive index between the holes and the semiconductor that constitute the two-dimensional photonic crystal widens, and the diffraction efficiency of the two-dimensional photonic crystal can be improved.

As mentioned above, according to the surface-emitting lasers including two-dimensional photonic crystals disclosed in Japanese Patent Laid-Open Nos. 2006-165309 and 2008-130731, the distance between the active layer and the two-dimensional photonic crystal is shortened to improve the characteristics of the surface-emitting lasers.

Meanwhile, the lattice constant of a two-dimensional photonic crystal is proportional to the wavelength of light introduced into the photonic crystal. Thus, the lattice constant of the photonic crystal must be decreased as the emission wavelength of the surface-emitting laser with the two-dimensional photonic crystal is shortened.

For example, the lattice constant of the photonic crystal is 160 nm when the emission wavelength is 405 nm in the surface-emitting laser with the photonic crystal consisted of GaN.

Thus, as the wavelength of the surface-emitting laser shortens, the radius of holes in the two-dimensional photonic crystal must be decreased.

Nitride semiconductors with emission wavelengths in the ultraviolet to green regions have high covalent bond energy and thus it is difficult to perform fine processing on such semiconductors by chemical etching.

Thus, it is difficult to decrease the radius of each hole of the two-dimensional photonic crystal of the nitride semiconductors.

However, if the radius of the holes in the two-dimensional photonic crystal is large, the surface-emitting laser with the two-dimensional photonic crystal exhibits a decrease in gain in the active layer and a decrease in diffraction efficiency of the two-dimensional photonic crystal, resulting in deterioration of the laser characteristics.

### SUMMARY OF THE INVENTION

It is desirable to provide a surface-emitting laser with a two-dimensional photonic crystal that can improve device characteristics by suppressing the decrease in gain of the active layer and the decrease in diffraction efficiency of the two-dimensional photonic crystal even when it is difficult to reduce size of holes in the two-dimensional photonic crystal.

An aspect of the present invention provides a surface-emitting laser including an active layer and a two-dimensional photonic crystal that includes a semiconductor and a dielectric material that has a refractive index different from that of the semiconductor and acts as photonic crystal holes arranged in a two-dimensional periodical structure. The surface-emitting laser has resonant modes in an in-plane direction of the two-dimensional photonic crystal. Moreover, r≧0.22a, where a is the lattice constant of the two-dimensional photonic crystal, and r is the radius of the dielectric material acting as the holes of the two-dimensional photonic crystal. The dielectric material has a refractive index that causes the coupling coefficient of the two-dimensional photonic crystal to exhibit an increasing tendency as the distance between the active layer and the two-dimensional photonic crystal shortens.

The present invention can provide a surface-emitting laser with a two-dimensional photonic crystal that can improve device characteristics by suppressing the decrease in gain of the active layer and the decrease in diffraction efficiency of the two-dimensional photonic crystal even when it is difficult to reduce the size of holes of two-dimensional photonic crystal.

Further features of the present invention will become apparent from the following description of exemplary embodiments with reference to the attached drawings.

### BRIEF DESCRIPTION OF THE DRAWINGS

FIG. 1 is a schematic cross-sectional view of a surface-emitting laser according to a first embodiment of the present invention.

FIG. 2 is a schematic cross-sectional view of a structure used in the calculation according to the first embodiment.

FIGS. 3A and 3B are graphs showing results of the calculation of the first embodiment.

FIGS. 4A and 4D are graphs showing results of the calculation of the first embodiment.

FIGS. 5A and 5E are graphs showing results of the calculation of the first embodiment.

FIG. 6 is a graph showing results of the calculation of the first embodiment.

FIG. 7 is a graph showing results of the calculation of the first embodiment.

FIG. 8 is a graph showing results of the calculation of the first embodiment.

FIG. 9 is a graph showing results of calculation of the embodiment when the two-dimensional photonic crystal is arranged into a square grid pattern.

FIGS. 10A to 10C are cross-sectional views showing steps of producing a surface-emitting laser of Example 1 of the present invention.

### DESCRIPTION OF THE EMBODIMENTS

The inventors of the present invention have found that when the radius of holes of a two-dimensional photonic crystal is large, it helps to improve the resonance characteristics of a surface-emitting laser by decreasing the difference in refractive index between a semiconductor that constitutes the two-dimensional photonic crystal and dielectric material acting as the holes of the two-dimensional photonic crystal.

According to Japanese Patent Laid-Open Nos. 2006-165309 and 2008-130731, the holes of the two-dimensional photonic crystal are left unfilled (occupied by gas, such as air) or filled with a material having a low refractive index so that the difference in refractive index between the semiconductor that constitutes the two-dimensional photonic crystal and the holes is widened.

In contrast, the inventors have found that it is actually favorable to decrease the difference in refractive index when the radius of holes of the two-dimensional photonic crystal is large.

A first embodiment of a surface-emitting laser with a two-dimensional photonic crystal will now be described with reference to the drawings.

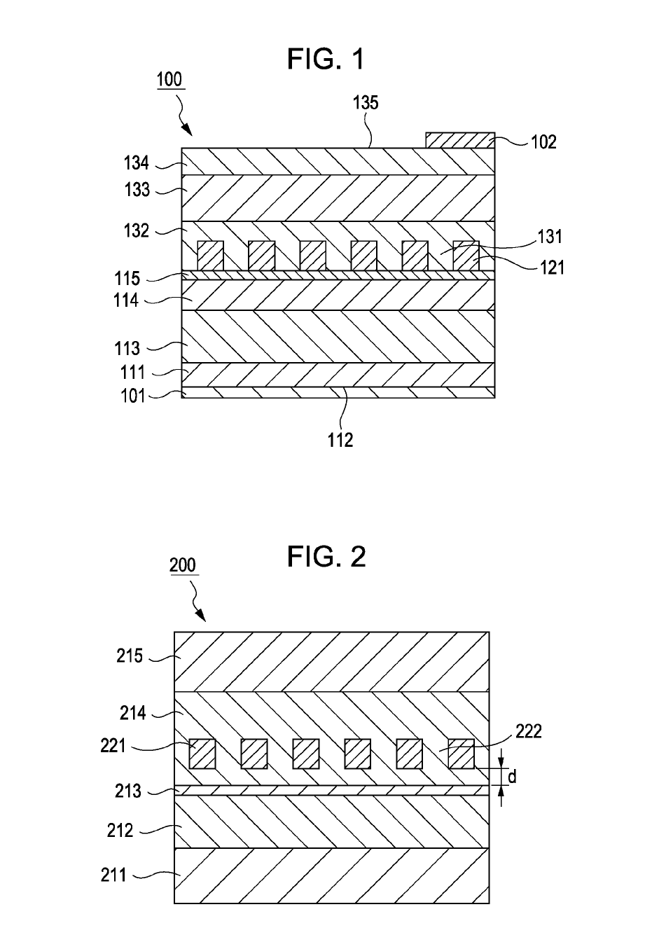

FIG. 1 is a cross-sectional view showing the structure of a surface-emitting laser with a two-dimensional photonic crystal according to this embodiment.

A surface-emitting laser 100 includes a lower contact layer 111, a lower cladding layer 113, a lower optical guide layer 114, an active layer 115, dielectric material 121, a two-dimensional photonic crystal 131, an upper optical guide layer 132 including the two-dimensional photonic crystal 131, an upper cladding layer 133, and an upper contact layer 134.

In this embodiment, a semiconductor layer included in the two-dimensional photonic crystal 131 is composed of GaN which has a refractive index of 2.54, and the periodically aligned dielectric material 121 is a substance (or alternatively a combination and/or composition of multiple substances which together) has a refractive index of 2.0 to 2.3 inclusive.

A process for making the upper optical guide layer 132 including the two-dimensional photonic crystal 131 will now be described.

After forming the active layer 115, the dielectric material 121 composed of hafnium oxide (refractive index: 2.1) or the like is arranged on the active layer 115 to form a two-dimensional periodical structure having a resonance mode in the in-plane direction.

Then the upper optical guide layer 132 is formed on the active layer 115 and the dielectric material 121 arranged to have the shape of the photonic crystal on the active layer 115 by, for example, a metal organic chemical vapor deposition (MOCVD) technique or a molecular beam epitaxy (MBE) technique as described below.

For example, an n-type GaN layer is deposited at regions where the dielectric material 121 is not formed so as to bury the dielectric material 121. Using this method, the upper optical guide layer 132 including the two-dimensional photonic crystal 131 composed of the dielectric material 121 is formed.

In this embodiment, the active layer 115 is adjacent to the two-dimensional photonic crystal 131. Alternatively, the active layer 115 may be distant from the two-dimensional photonic crystal 131, in which case, after the active layer 115 is formed, part of the upper optical guide layer 132 composed of, for example, n-type GaN is deposited on the active layer 115 to a desired thickness. Then, by forming the dielectric material 121, the distance between the two-dimensional photonic crystal 131 and the active layer 115 can be freely set.

According to Japanese Patents Laid-Open Nos. 2006-165309 and 2008-130731, any material acting as the holes of the two-dimensional photonic crystal is of low refractive index, and the difference in refractive index between the semiconductor constituting the two-dimensional photonic crystal and the material acting as the holes is large.

In contrast, according to this embodiment, the holes are filled with material having a refractive index in a range of 2.0 to 2.3 to reduce the difference in refractive index between the semiconductor and the dielectric material 121 acting as the holes of the two-dimensional photonic crystal.

The effects of the above-discussed differences on the characteristics of the surface-emitting laser will now be described.

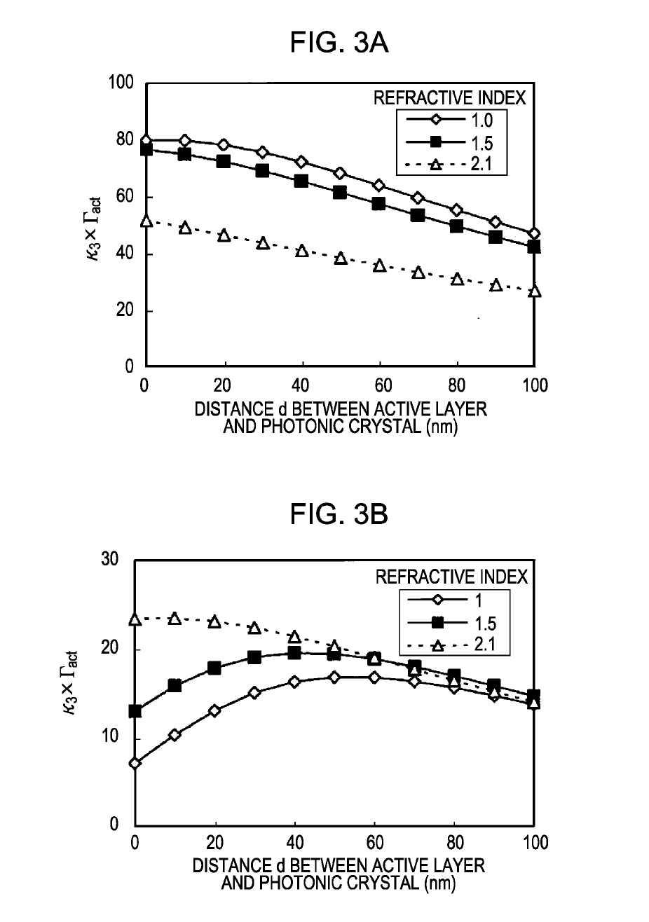

FIG. 2 is a schematic view of a structure used for calculating the coupling coefficient κ₃ of the photonic crystal and the optical confinement factor Γ_{act} of the active layer of this embodiment.

To study the effects of the above-mentioned differences on the characteristics of the surface-emitting laser, the coupling coefficient κ₃ of a two-dimensional photonic crystal 222 and the optical confinement factor Γ_{act} of an active layer 213 of a surface-emitting laser 200 were calculated using the structure shown in FIG. 2. The coupling coefficient κ₃ of the two-dimensional photonic crystal 222 is proportional to the diffraction efficiency of the two-dimensional photonic crystal 222, and the optical confinement factor Γ_{act} of the active layer 213 is proportional to the gain of the active layer. In other words, the product κ₃×Γ_{act} of the coupling coefficient κ₃ of the two-dimensional photonic crystal 222 and the optical confinement factor Γ_{act} of the active layer 213 strongly represents the resonance characteristics of the surface-emitting laser.

In the calculation, the thickness of a lower optical guide layer 212 and the thickness of an upper optical guide layer 214 including the two-dimensional photonic crystal 222 were set to 150 nm each, the height of dielectric material 221 was set to 100 nm, and the thickness of a lower cladding layer 211 and the thickness of an upper cladding layer 215 were each set to an infinity. Also in the calculation, the refractive indices of the lower cladding layer 211 and the upper cladding layer 215 were set to 2.5 each, the refractive indices of the lower optical guide layer 212 and the upper optical guide layer 214 were set to 2.54 each, and the refractive index of the active layer 213 set to 2.73. The emission wavelength was set to 405 nm.

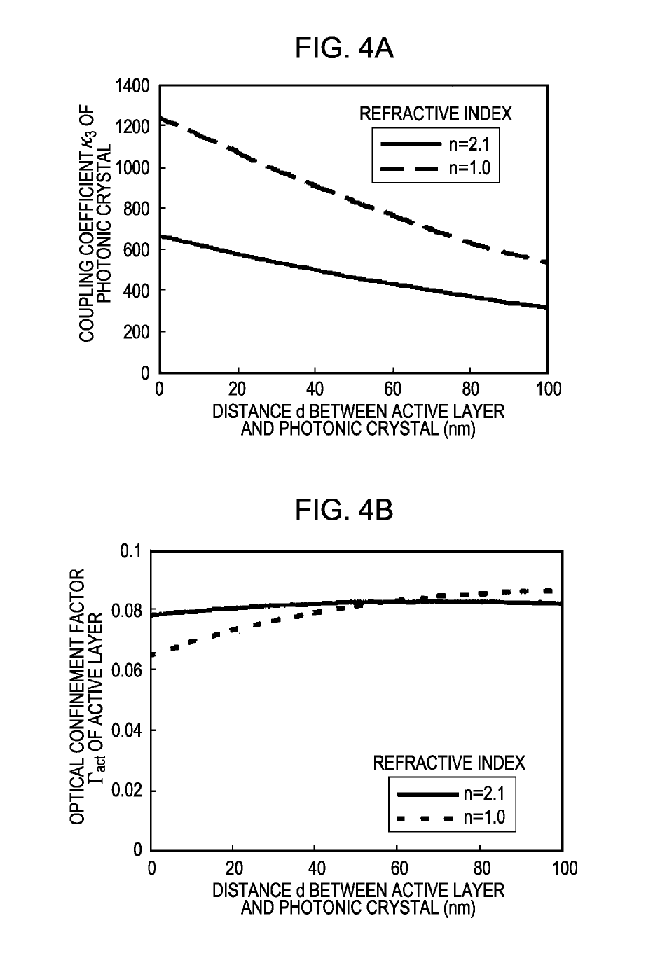

FIGS. 3A and 3B show the results obtained from κ₃×Γ_{act}, i.e., the product of the coupling coefficient κ₃ of the photonic crystal and the optical confinement factor Γ_{act} of the active layer plotted against the distance between the active layer and the two-dimensional photonic crystal using the refractive index of the dielectric material as the parameter.

### Calculation Example

### Radius=0.15a

FIG. 3A shows the results obtained from κ₃×Γ_{act} when the radius of the dielectric material acting as the holes of the two-dimensional photonic crystal is 0.15a. In other words, the graph shows results obtained from κ₃×Γ_{act} plotted against the distance d between the active layer 213 and the photonic crystal 222 where columnar dielectric material 221 arranged into a square grid pattern has a radius r satisfying r=0.15a, where a represents the lattice constant of the two-dimensional photonic crystal 222. In the calculation, the refractive index of the dielectric material 221 used as the parameter was set to 1.0, 1.5, and 2.1.

When the radius r of the dielectric material 221 acting as the holes is 0.15a, the product κ₃×Γ_{act} increases with a decrease in refractive index of the dielectric material 221 irrespective of the distance d between the active layer 213 and the two-dimensional photonic crystal 222. Thus, the refractive index n of the dielectric material 221 may be 1.0.

### Calculation Example

### Radius=0.25a

FIG. 3B shows the results obtained from κ₃×Γ_{act} where the radius r of the dielectric material 221 acting as the holes is 0.25a. As the radius r of the dielectric material 221 increases from 0.15a to 0.25a, κ₃×Γ_{act} decreases irrespective of the refractive index of the dielectric material 221.

As the refractive index of the dielectric material 221 increases from 1.0 to 2.1, the ratio of decrease in κ₃×Γ_{act} caused by the increase in radius of the dielectric material 221 decreases. As a result, when the radius r of the dielectric material 221 is 0.25a, the maximum value of κ₃×Γ_{act} increases with the refractive index of the dielectric material 221. When the distance d between the active layer 213 and the two-dimensional photonic crystal 222 is 40 nm or less, κ₃×Γ_{act} increases with the refractive index of the dielectric material 221. Thus, the refractive index n of the dielectric material 221 may be 2.1. In other words, the refractive index of the dielectric material is desirably high as the radius of the dielectric material acting as the holes of the two-dimensional photonic crystal increases.

### Relationship Among Radius of Dielectric Material Acting as Holes of Two-Dimensional Photonic Crystal, Coupling Coefficient κ₃, and Optical Confinement Factor Γ_{act}

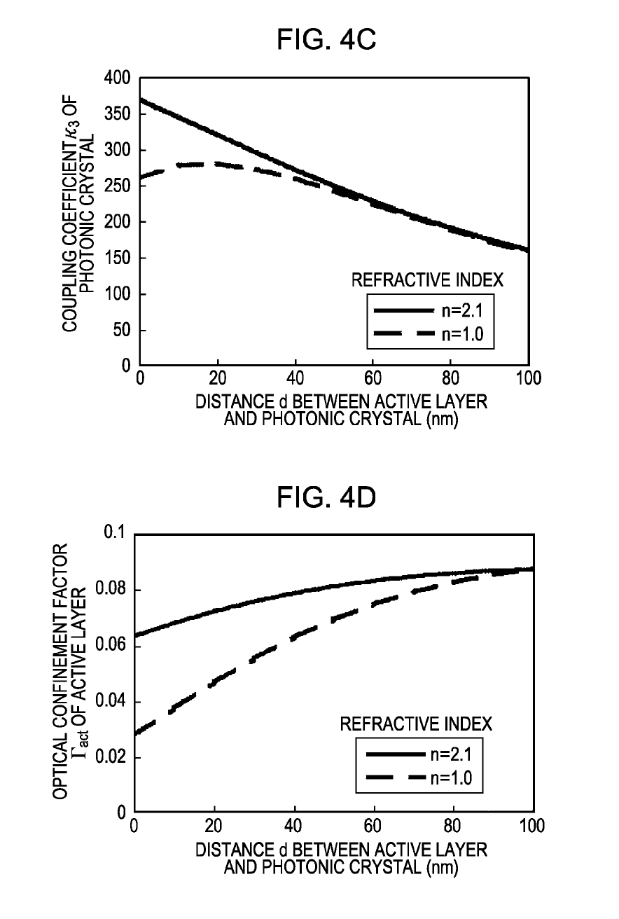

FIGS. 4A to 4D show the results of calculation of the coupling coefficient κ₃ of the photonic crystal and the optical confinement factor Γ_{act} of the active layer plotted against the distance between the active layer 213 and the two-dimensional photonic crystal 222 by using the refractive index of the dielectric material as a parameter. FIG. 4A shows the results of calculating κ₃ when the radius of the dielectric material acting as the holes of the two-dimensional photonic crystal is 0.15a. FIG. 4B shows the results of calculating Γ_{act} when the radius of the dielectric material is 0.15a. In these graphs, the calculated κ₃ and Γ_{act} are plotted against the distance d between the active layer 213 and the two-dimensional photonic crystal 222 where the radius r of the dielectric material 221 is 0.15a and the refractive index of the dielectric material 221 is 1.0 and 2.1 to study the results described above in further detail. Similarly, FIG. 4C shows the results of calculating κ₃ where the radius of the dielectric material is 0.25a. FIG. 4D shows the results of calculating Γ_{act} when the radius of the dielectric material is 0.25a.

As shown in FIG. 4A, when the radius r of the dielectric material 221 is 0.15a, the coupling coefficient κ₃ of the two-dimensional photonic crystal 222 shows an increasing tendency as the distance d between the active layer 213 and the two-dimensional photonic crystal 222 decreases.

This is because the amount of light introduced into the two-dimensional photonic crystal 222 from the active layer 213 is increased as the distance between the active layer 213 and the two-dimensional photonic crystal 222 decreases.

When the distance d between the active layer 213 and the two-dimensional photonic crystal 222 is 0 nm (adjacent) and the refractive index of the dielectric material 221 decreases from 2.1 to 1.0, κ₃ increases factor of 1.86.

This is because the diffraction efficiency of the two-dimensional photonic crystal 222 increases with the difference between the refractive index of the semiconductor constituting the two-dimensional photonic crystal 222 (2.54 when the semiconductor is GaN) and the refractive index of the dielectric material 221 acting as the holes of the two-dimensional photonic crystal 222.

In contrast, as shown in FIG. 4B, the optical confinement factor Γ_{act} of the active layer 213 shows a slight decreasing tendency with the decrease in the distance d between the active layer 213 and the two-dimensional photonic crystal 222. Moreover, Γ_{act} does not significantly change by the difference in the refractive index of the dielectric material 221. These results show that κ₃×Γ_{act} is strongly affected by the value of κ₃, which depends strongly on both the distance d between the active layer 213 and the two-dimensional photonic crystal 222 and the refractive index of the dielectric material 221. Thus, κ₃×Γ_{act} in the case of the refractive index of 2.1 is larger than those of 1.0.

As shown in FIG. 4C, when the radius r of the dielectric material 221 is 0.25a and the refractive index of the dielectric material 221 is 2.1, the coupling coefficient κ₃ of the two-dimensional photonic crystal 222 monotonically increases with a decrease in distance d between the active layer 213 and the two-dimensional photonic crystal 222. However, when the refractive index of the dielectric material 221 is 1.0, the ratio of increase in κ₃ with a decrease in the distance d decreases as the distance d becomes 50 nm or smaller. When the distance is 20 nm or smaller, the coupling coefficient κ₃ of the two-dimensional photonic crystal 222 shows a decreasing tendency instead of the increasing tendency. This is because the decrease in the mean refractive index of the two-dimensional photonic crystal 222 suppresses introduction of light into the two-dimensional photonic crystal 222.

In other words, as the radius r of the dielectric material 221 increases from 0.15a to 0.25a, the filling percentage of the dielectric material 221 in the two-dimensional photonic crystal 222 increases from 7.1% to 19.6%. In such a case, when the refractive index of the dielectric material 221 decreases from 2.1 to 1.0, the mean refractive index of the two-dimensional photonic crystal 222 drops from 2.45 to 2.24. As a result, the emitting light from the active layer 213 is not easily introduced into the two-dimensional photonic crystal 222.

This effect becomes stronger as the two-dimensional photonic crystal 222 becomes closer to the center of the guided mode in the surface-emitting laser 200.

Thus, when the distance d between the active layer 213 and the two-dimensional photonic crystal 222 is decreased, κ₃ is determined by the following two ratios: the ratio of an increase in amount of light introduced into the two-dimensional photonic crystal 222 due to the decrease in the distance d and the ratio of a decrease in amount of light introduced into the two-dimensional photonic crystal 222 attributable to a low mean refractive index of the two-dimensional photonic crystal 222.

As shown in FIG. 4D, the optical confinement factor Γ_{act} of the active layer 213 shows a decreasing tendency with the decreasing distance between the active layer 213 and the two-dimensional photonic crystal 222.

The ratio of decrease increases as the refractive index of the dielectric material 221 decreases from 2.1 to 1.0.

As with κ₃ described above, this is because introduction of light into the two-dimensional photonic crystal 222 is suppressed by lowering of the mean refractive index of the two-dimensional photonic crystal 222. This effect grows stronger as the distance between the active layer 213 and the two-dimensional photonic crystal 222 shortens.

As shown above, when the radius r of the dielectric material 221 increases from 0.15a to 0.25a, the effect of the refractive index of the dielectric material 221 on the mean refractive index of the two-dimensional photonic crystal 222 becomes stronger. Thus, as shown in FIG. 3B, the maximum value of κ₃×Γ_{act} increases by increasing the refractive index of the dielectric material 221.

Relationship Among Maximum Value of κ₃×Γ_{act}, Refractive Index, and Distance d

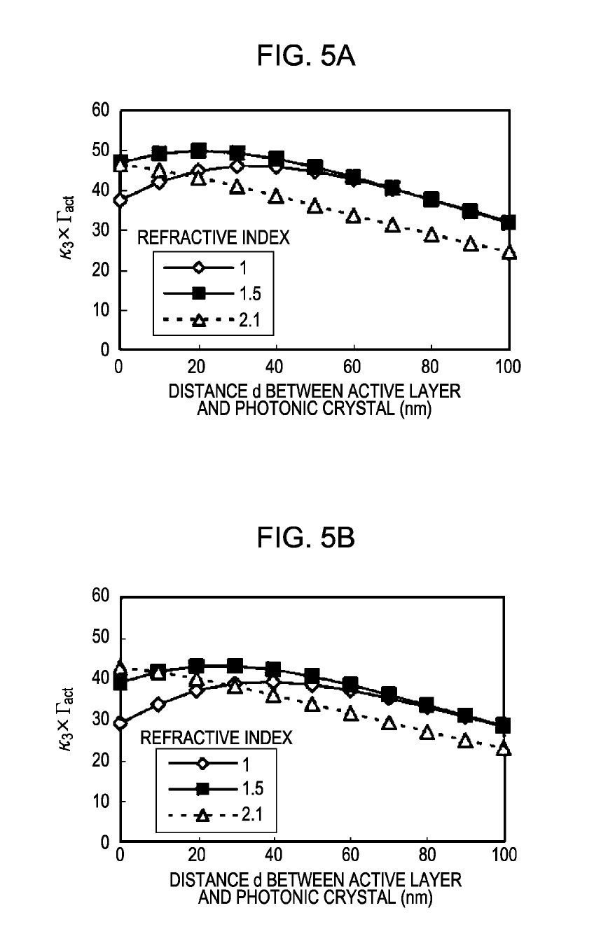

FIGS. 5A to 5E show the results obtained from κ₃×Γ_{act}, the product of the coupling coefficient κ₃ and the optical confinement factor Γ_{act}, plotted against the distance between the active layer and the two-dimensional photonic crystal using the refractive index of the dielectric material as a parameter.

In order to study the effect of the radius r of the dielectric material 221 on the κ₃×Γ_{act} in further detail, the radius r was changed to 0.20a, 0.21a, 0.22a, 0.23a, and 0.24a in calculating κ₃×Γ_{act} versus the distance d between the active layer 213 and the two-dimensional photonic crystal 222.

FIG. 5A shows the results of κ₃×Γ_{act} when the radius of the dielectric material 221 is 0.20a.

The calculation was conducted using the refractive index of the dielectric material 221 as the parameter, which was set to 1.0, 1.5, and 2.1.

Similarly, FIG. 5B shows the results of κ₃×Γ_{act} when the radius of the dielectric material 221 is 0.21a, FIG. 5C shows the results when the radius is 0.22a, FIG. 5D shows the results when the radius is 0.23a, and FIG. 5E shows the results when the radius is 0.24a.

On the basis of these results, Table 1 shows the distance d and the refractive index of the dielectric material which give the maximum value of κ₃×Γ_{act} relative to the radius r of the dielectric material. When the radius r is 0.22a or more, κ₃×Γ_{act} can take a larger value by increasing the refractive index of the dielectric material 221 to 2.1.

The radius r of 0.22a or more is equivalent to 35 nm or more. In such a case, the filling percentage of the dielectric material 221 in the two-dimensional photonic crystal 222 is 15.2% or more.

TABLE 1

| | | Refractive index when | Distance d when |
|---|---|---|---|
| | Maximum value | κ₃ × Γ_{act} | κ₃ × Γ_{act} |
| Radius r | of κ₃ × Γ_{act} | is maximum | is maximum (nm) |
| 0.20a | 49.91 | 1.5 | 20 |
| 0.21a | 43.15 | 1.5 | 30 |
| 0.22a | 38.43 | 2.1 | 0 |
| 0.23a | 33.66 | 2.1 | 0 |
| 0.24a | 28.62 | 2.1 | 0 |

### Relationship Between Refractive Index of Dielectric Material and κ₃×Γ_{act}

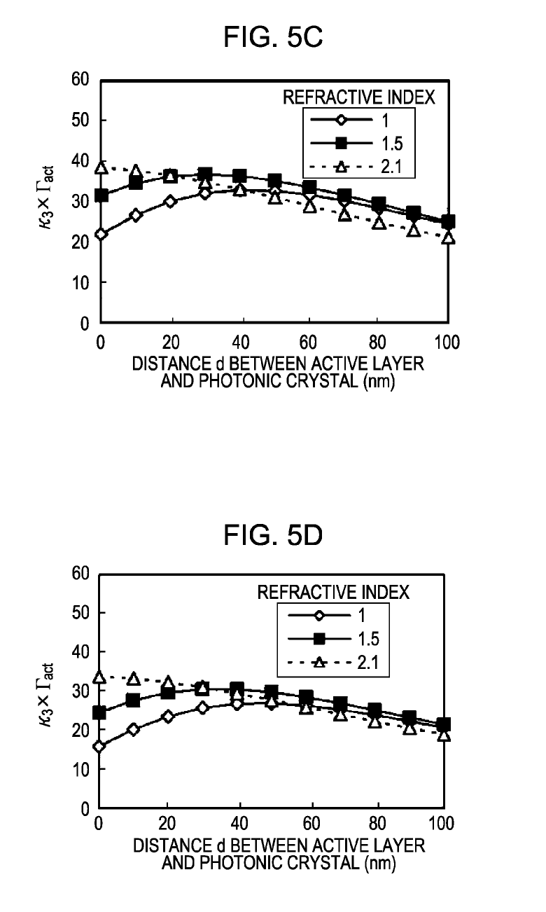

In order to study the effect of the refractive index of the dielectric material 221 on κ₃×Γ_{act} in further detail, κ₃×Γ_{act} was calculated versus the refractive index of the dielectric material 221 using the radius of the dielectric material 221 as a parameter, as shown in FIG. 6.

The radius r was set to 0.15a, 0.20a, 0.21a, 0.22a, 0.23a, 0.24a, and 0.25a. The distance d between the active layer 213 and the two-dimensional photonic crystal 222 was set to 0 nm (adjacent).

As the radius r increases, the refractive index of the dielectric material 221 that can give maximum κ₃×Γ_{act becomes higher.}

When the radius r is 0.22a or more, the refractive index of the dielectric material 221 that can give maximum κ₃×Γ_{act} is 2.0 or more.

When the refractive index of the dielectric material 221 exceeds 2.3, κ₃×Γ_{act} decreases rapidly. This is because of the decrease in the coupling coefficient κ₃ of the two-dimensional photonic crystal 222.

The reason therefor is that when the difference in refractive index between the semiconductor constituting the two-dimensional photonic crystal 222 (2.54 if the semiconductor is GaN) and the dielectric material 221 narrows, the diffraction efficiency of the two-dimensional photonic crystal 222 is degraded.

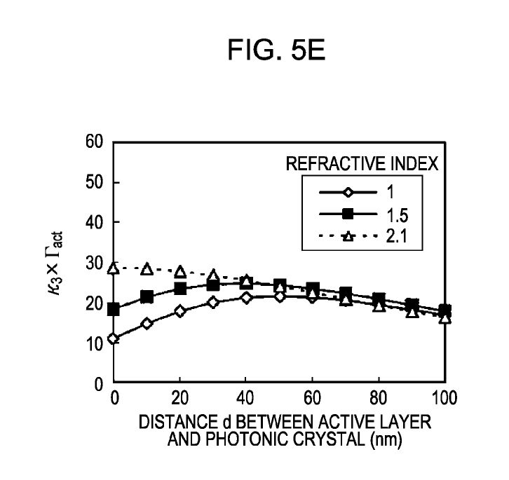

FIG. 7 shows the results of calculating κ₃×Γ_{act} plotted against the distance d when the radius of the dielectric material is 0.22a and the refractive index of the dielectric material is changed from 1.5 to 2.3 in an increment of 0.1.

As shown in FIG. 7, when the radius r is 0.22a, κ₃×Γ_{act} shows a monotonically increasing tendency with the decreasing distance d at a refractive index of 2.0 or more. In contrast, for the refractive index in the range of 1.5 to 1.9, κ₃×Γ_{act} shows a decreasing tendency as the distance d decreases. As such, the tendency of κ₃×Γ_{act} associated the adjacent arrangement between the active layer and the two-dimensional photonic crystal differs between when the refractive index is 1.9 and when the refractive index is 2.0.

Thus, the refractive index may be 2.0 or more when the radius r is 0.22a. However, as shown in FIG. 7, when the refractive index of the dielectric material 221 is 2.3 or more, κ₃×Γ_{act} becomes small. This tendency observed with the refractive index is also observed when the radius r is 0.22a or more.

As understood from above, (in contrast to the technology disclosed in Japanese Patent Laid-Open No. 2006-165309), in this embodiment, κ₃×Γ_{act} can be increased by providing dielectric material having a high refractive index when the radius r of the dielectric material 221 in the two-dimensional photonic crystal 222 is 0.22a or more. In the case where the radius r is 0.22a, increasing the refractive index of the dielectric material 221 to 2.0 or more can prevent κ₃×Γ_{act} from exhibiting a decreasing tendency with the decreasing distance d between the active layer and the two-dimensional photonic crystal.

However, when the refractive index of the dielectric material 221 is 2.3 or more, κ₃×Γ_{act} becomes small. Thus, the material for the dielectric material 221 desirably has a refractive index of 2.0 or more and 2.3 or less.

Examples of such a material include hafnium oxide (refractive index: about 2.1), tantalum oxide (refractive index: about 2.3), titanium oxide (refractive index: about 2.2), zirconium oxide (refractive index: about 2.2), niobium oxide (refractive index: about 2.3), and aluminum nitride (refractive index: about 2.2).

While the calculation performed in this embodiment involves the two-dimensional photonic crystal 222 arranged into a square grid pattern, the same calculation was conducted on the two-dimensional photonic crystal 222 arranged into a triangular grid pattern to investigate the effect of the shape of the two-dimensional photonic crystal 222 on κ₃×Γ_{act}.

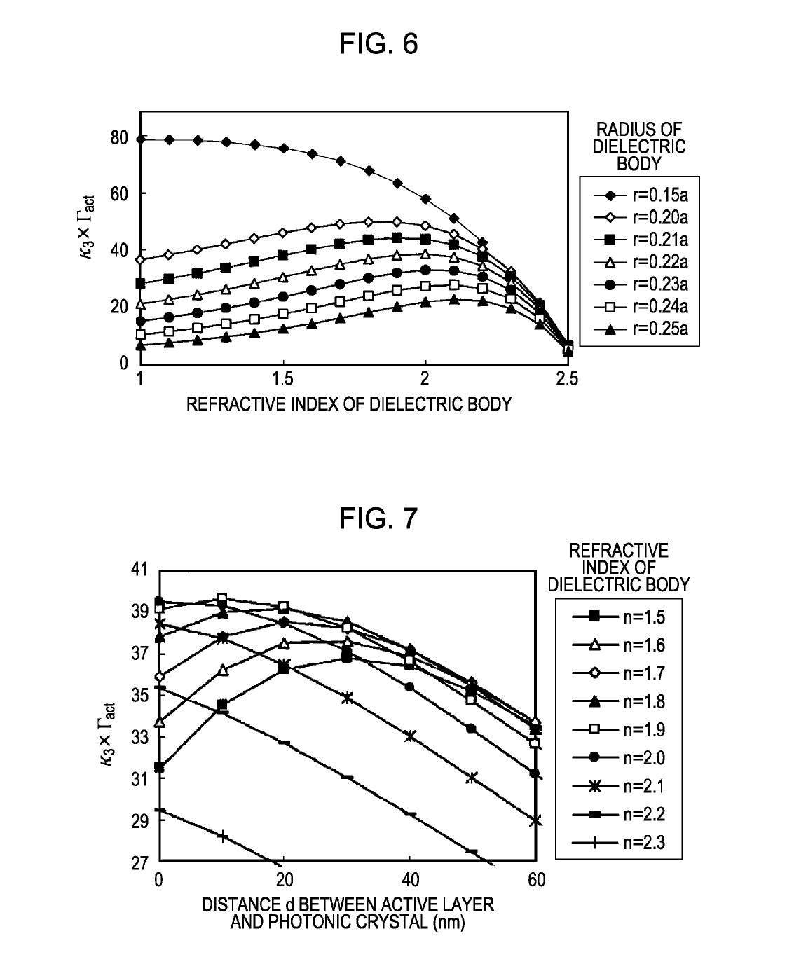

FIG. 8 shows κ₃×Γ_{act} plotted against the refractive index of the dielectric material 221 using the radius of the dielectric material 221 acting as the holes of the two-dimensional photonic crystal 222 as a parameter when the two-dimensional photonic crystal 222 is arranged into a triangular grid pattern.

In the graph, the radius r is set to 0.20a, 0.21a, 0.22a, 0.23a, 0.24a, and 0.25a. The distance d between the active layer 213 and the two-dimensional photonic crystal 222 is set to 0 nm (adjacent).

As the radius of the dielectric material 221 increases, the refractive index of the dielectric material 221 that gives maximum κ₃×Γ_{act} increases. This tendency is similar to the case where the two-dimensional photonic crystal 222 is arranged into a square grid pattern.

When the radius r of the dielectric material 221 is 0.22a or more, the filling percentage of the dielectric material 221 in the two-dimensional photonic crystal 222 is 17.6% or more.

This shows that the shape of the two-dimensional photonic crystal 222 of this embodiment is not limited to a square grid pattern and may be a triangular grid pattern.

While calculation was conducted in this embodiment involving the columnar shaped holes filled with the dielectric material 221, the same calculation was conducted for prismatic shaped holes filled with the dielectric material 221 to investigate the effect of the shape of the dielectric material 221 acting the holes of the two-dimensional photonic crystal on κ₃×Γ_{act}.

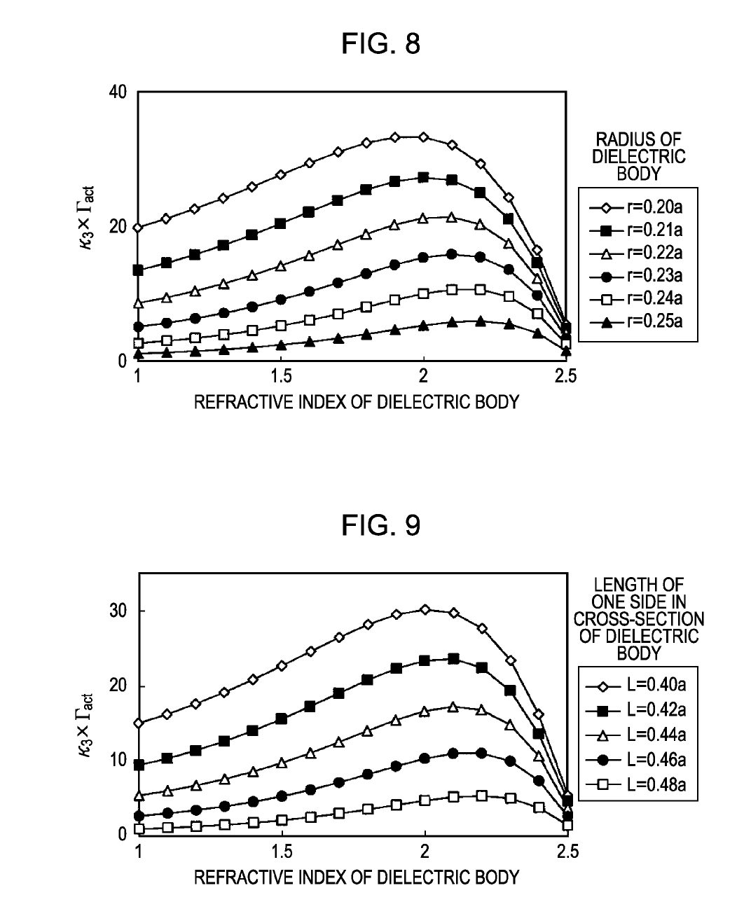

FIG. 9 shows κ₃×Γ_{act} plotted against the refractive index of the dielectric material 221 by using the length of one side of a cross-section of the dielectric material 221 as the parameter, in the case where the prismatic shaped dielectric material 221 acting as the holes of the two-dimensional photonic crystal 222 are arranged into a square grid pattern and have square-shaped cross-sections.

The length L of one side of the cross-section of the dielectric material 221 was set to 0.40a, 0.42a, 0.44a, 0.46a, and 0.48a.

The distance d between the active layer 213 and the two-dimensional photonic crystal 222 was set to 0 nm (adjacent).

The results show that the refractive index of the dielectric material 221 that gives maximum κ₃×Γ_{act} increases with the length L. This is a tendency similar to that of the case where the dielectric material 221 has a columnar shape.

The refractive index of the dielectric material 221 that gives maximum κ₃×Γ_{act} at a length L of 0.40a or more is 2.0 or more. Here, the length L of 0.40a or more is equivalent to 64 nm or more and the filling percentage of the dielectric material 221 in the two-dimensional photonic crystal 222 is 16% or more.

These results show that the shape of the dielectric material 221 is not limited to columnar and, for example, may be prismatic.

According to the structures of the present embodiment mentioned above, the decrease in gain of the active layer can be suppressed even when the holes in the two-dimensional photonic crystal are relatively large. Moreover, the diffraction efficiency of the two-dimensional photonic crystal can be suppressed and device characteristics can be improved.

### EXAMPLES

Further embodiments of the present invention will now be described as EXAMPLE 1 and EXAMPLE 2.

### Example 1

In EXAMPLE 1, a surface-emitting laser with a two-dimensional photonic crystal according to the present invention is described.

The basic structure of the surface-emitting laser of this example is identical to the surface-emitting laser 100 of the embodiment shown in FIG. 1.

In this Example, as shown in FIG. 1, a surface-emitting laser 100 includes a p-type contact layer 111, a p-type cladding layer 113, a p-type optical guide layer 114, an active layer 115, a two-dimensional photonic crystal 131, an n-type optical guide layer 132 including the two-dimensional photonic crystal, an n-type cladding layer 133, an n-type contact layer 134, and electrodes 101 and 102.

The p-type optical guide layer 114 and the n-type optical guide layer 132 including the two-dimensional photonic crystal are respectively composed of a p-type GaN and an n-type GaN. The p-type cladding layer 113 and the n-type cladding layer 133 are respectively composed of a p-type AlGaN and an n-type AlGaN and respectively have refractive indices lower than those of the p-type optical guide layer 114 and the n-type optical guide layer 132.

The p-type optical guide layer 114, the n-type optical guide layer 132 including the two-dimensional photonic crystal, the p-type cladding layer 113, and the n-type cladding layer 133 function as conduction layers in which carriers to be injected to the active layer 115 are conducted.

The p-type optical guide layer 114 and the n-type optical guide layer 132 sandwich the active layer 115. The p-type cladding layer 113 and the n-type cladding layer 133 sandwich the p-type optical guide layer 114, the active layer 115, and the n-type optical guide layer 132 to form a separated confinement heterostructure (SCH).

As a result, carriers that contribute to emission are confined in the active layer 115, light emitted from the active layer 115 is confined in the active layer 115, the p-type optical guide layer 114, and the n-type optical guide layer 132.

The active layer 115 has a multiple quantum well structure composed of nitride semiconductors. The well and barrier layers of the multiple quantum well structure are respectively composed of InGaN and GaN. The bandgap of the well layer is smaller than that of the barrier layer, the p-type optical guide layer 114, and the n-type optical guide layer 132 including the two-dimensional photonic crystal.

The active layer 115 emits light as carriers are injected. Note that although the active layer 115 of this embodiment has the multiple quantum well structure described above, it may alternatively have a single quantum well structure.

The electrode 102 is disposed on an n-type contact surface 135 and the electrode 101 is disposed on a p-type contact surface 112. As voltage is applied between the electrodes 101 and 102, the active layer 115 emits light and the light is introduced into the two-dimensional photonic crystal 131. The light that matches the period of the two-dimensional photonic crystal 131 is repeatedly diffracted with the two-dimensional photonic crystal 131, thereby generating a standing wave and defining the phase condition. The light having a phase defined by the two-dimensional photonic crystal 131 is fed back to the light in the active layer 115 through diffraction to generate a standing wave. This standing wave satisfies the wavelength and phase conditions of the light defined by the two-dimensional photonic crystal 131. As a result, the light resonates with the two-dimensional photonic crystal 131 and is amplified, and coherent light is surface-emitted from the n-type contact surface 135.

The two-dimensional photonic crystal 131 includes dielectric material 121 arranged into a grid pattern. The dielectric material 121 is composed of hafnium oxide (HfO₂).

The dielectric material 121 of this example is not limited to hafnium oxide (refractive index: 2.1) and may be any other material that has a refractive index of 2.0 or more and 2.3 or less. Examples of such a material include tantalum oxide (refractive index: about 2.3), titanium oxide (refractive index: about 2.2), zirconium oxide (refractive index: about 2.2), niobium oxide (refractive index: about 2.3), and aluminum nitride (refractive index: about 2.2).

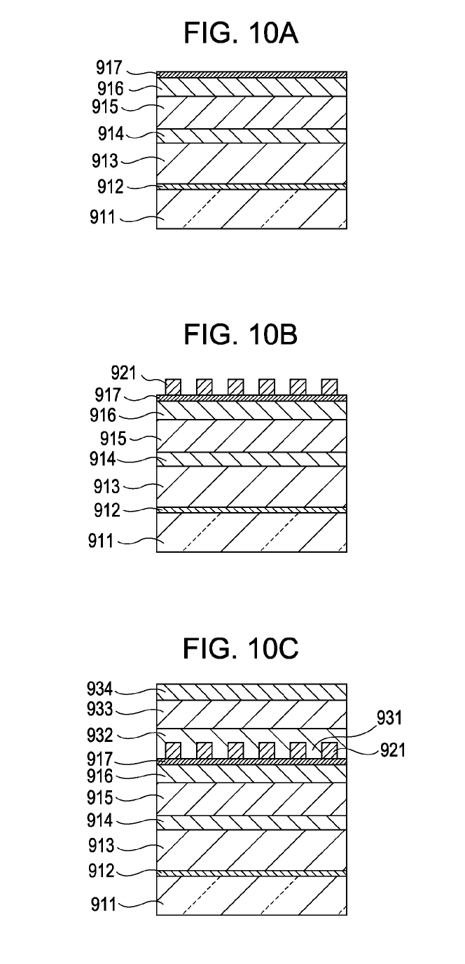

Next, a method for fabricating the surface-emitting laser 100 of this example is described with reference to FIGS. 10A to 10C.

First, as shown in FIG. 10A, a GaN buffer layer 913 is formed on a strain-absorbing layer 912 on a sapphire substrate 911 by MOCVD. The GaN buffer layer 913 is composed of GaN and used for reducing the number of dislocations.

A p-type contact layer 914 composed of p-type GaN, a p-type cladding layer 915 composed of p-type AlGaN, a p-type optical guide layer 916 composed of p-type GaN, and an active layer 917 of multiple quantum well structure composed of InGaN and GaN are sequentially formed in that order on the GaN buffer layer 913 to form a multilayer structure.

The substrate 911 used in this example is not limited to the sapphire substrate and may be a silicon substrate, for example.

Next, after a hafnium oxide film of thickness of 100 nm is formed using an electron-beam vapor deposition apparatus, a resist film having a shape of a photonic crystal is formed on the hafnium oxide film by electron beam exposure. The hafnium oxide film is dry-etched using the resist film as a mask.

Then the resist film is removed to form dielectric material 921 that has a shape of a two-dimensional photonic crystal having a resonance mode in the in-plane direction, as shown in FIG. 10B.

Referring now to FIG. 10C, an n-type GaN layer is deposited on the active layer 917 at regions where the dielectric material 921 is not formed.

As a result, the dielectric material 921 is buried and an n-type optical guide layer 932 including a two-dimensional photonic crystal 931 composed of the dielectric material 921 is formed.

Then an n-type cladding layer 933 composed of n-type AlGaN and an n-type contact layer 934 composed of n-type GaN are sequentially formed in that order to form a multilayer structure.

In this example, the method for fabricating the two-dimensional photonic crystal 931 is not limited to that described above. For example, wet etching may be employed instead of the dry etching to form the dielectric material 921.

Alternatively, the two-dimensional photonic crystal 931 may be formed using a lift-off technique after depositing a hafnium oxide film on the resist film of a photonic crystal shape on the active layer 917.

Alternatively, a hafnium oxide film may be formed, using an electron beam vapor deposition apparatus, on a n-type GaN layer having photonic crystal holes formed by dry etching on the active layer 917.

According to this method, a two-dimensional photonic crystal 931 with holes filled with hafnium oxide is formed.

Subsequently, part of hafnium oxide not filling the holes is removed, and an n-type GaN layer is formed on the two-dimensional photonic crystal 931. As a result, an n-type optical guide layer 932 including the two-dimensional photonic crystal 931 including the holes filled with the dielectric material 921 is formed.

Alternatively, the two-dimensional photonic crystal 931 may be formed on another substrate and the substrates may be fusion-bonded by lamination.

In particular, apart from the structure shown in FIG. 10A, the n-type contact layer 934, the n-type cladding layer 933, and the n-type optical guide layer 932 including the two-dimensional photonic crystal 931 including the holes filled with the dielectric material 921 are sequentially formed on a releasing layer on another substrate in that order.

Next, the two substrates are fusion-bonded using a lamination technique by arranging the active layer 917 to oppose the two-dimensional photonic crystal 931. Then the releasing layer is removed to expose the n-type contact layer 934.

In this example, although the active layer 917 is adjacent to the two-dimensional photonic crystal 931, the distance between the active layer 917 and the two-dimensional photonic crystal 931 can be freely set.

In such a case, after the active layer 917 is formed, an n-type GaN film having a desired thickness is formed on the active layer 917 to form part of the n-type optical guide layer 932 and then the dielectric material 921 is formed.

As a result, the distance between the two-dimensional photonic crystal 931 and the active layer 917 can be freely set.

Next, the substrate 911 was separated by pyrolyzing the strain-absorbing layer 912 by a laser lift-off technique. Note that the method for removing the substrate 911 in this example is not limited to the method described above and may be any other suitable method such as mechanical polishing.

Then the GaN buffer layer 913 is dry-etched from the surface where the separation was performed in order to expose the p-type contact layer 914.

The method for exposing the p-type contact layer 914 is not limited to the method described above and may be any other suitable method.

Then, as shown in FIG. 1, an electrode 101 is formed on a contact surface 112 of the p-type contact layer 111, and an electrode 102 is formed on a contact surface 135 of the n-type contact layer 134 to form the surface-emitting laser 100.

In this example, the two-dimensional photonic crystal 131 is formed above the active layer 115.

However, the location of the two-dimensional photonic crystal 131 in the surface-emitting laser of the present invention is not particularly limited, and the two-dimensional photonic crystal 131 may be formed below the active layer 115.

Moreover, as shown in FIG. 10A, the p-type layers, the active layer, and the n-type layers are formed on the substrate 911 in that order in this example. Alternatively, the n-type layers, the active layer, and the p-type layers may be formed on the substrate 911 in that order.

### Example 2

Unlike Example 1, Example 2 involves a surface-emitting laser including a two-dimensional photonic crystal fabricated on an electrically conductive substrate.

First, p-type cladding layer composed of p-type AlGaN is deposited on a p-type SiC substrate by MOCVD.

Other basic structures are the same as Example 1 shown in FIG. 1. However, the step of separating the substrate is not performed, and the p-type electrode is directly formed on the backside (the surface opposite to the surface on which the semiconductor layer is deposited) of the p-type SiC substrate.

Compared with Example 1, Example 2 is advantageous in terms of production processes in that it does not require steps of separating the substrate in forming the p-type electrode and removing the GaN buffer layer by dry etching.

Moreover, since the SiC substrate has a closer lattice constant to that of GaN than the sapphire substrate, introduction of defects caused by lattice mismatch can be suppressed during the fabrication step (steps of depositing semiconductor layers)

In other words, compared with Example 1 that uses a sapphire substrate, Example 2 is advantageous in that a laser with high crystal quality can be fabricated.

Although a p-type SiC substrate is used in this example, an n-type SiC substrate may be used instead, and the n-type layers, the active layers, and the p-type layers may be formed in that order to form a surface-emitting laser. Alternatively, an n-type GaN substrate may be used as the n-type conductive substrate.

While the present invention has been described with reference to various exemplary embodiments, it is to be understood that the invention is not limited to the disclosed exemplary embodiments. The scope of the following claims is to be accorded the broadest interpretation so as to encompass all modifications and equivalent structures and functions.

This application claims the benefit of Japanese Patent Applications No. 2008-311864, filed Dec. 9, 2008, and No. 2009-105939, filed Apr. 24, 2009, which are hereby incorporated by reference herein in their entirety.

What is claimed is:

1. A surface-emitting laser comprising:
an active layer; and
a two-dimensional photonic crystal including:
a semiconductor, and
dielectric material that has a refractive index different from that of the semiconductor and acts as photonic crystal holes arranged in a two-dimensional periodical structure,
wherein the surface-emitting laser has a resonance mode in an in-plane direction of the two-dimensional photonic crystal;
r≧0.22a, where a is the lattice constant of the two-dimensional photonic crystal, and r is the radius of the dielectric material; and
the dielectric material has a refractive index that causes the coupling coefficient of the two-dimensional photonic crystal to exhibit an increasing tendency as the distance between the active layer and the two-dimensional photonic crystal shortens.

2. The surface-emitting laser according to claim 1, wherein the refractive index of the dielectric material is between 2.0 and 2.3 inclusive.

3. The surface-emitting laser according to claim 2, wherein the radius r of the dielectric material is 35 nm or more.

4. The surface-emitting laser according to claim 2, wherein the distance between the active layer and the two-dimensional photonic crystal is 40 nm or less.
